(19) United States
(12) Patent Application Publication
(10) Pub. No.: US 2009/0166796 A1
(43) Pub. Date: Jul. 2, 2009

(54) METHOD FOR MANUFACTURING INTEGRATED CIRCUIT AND SEMICONDUCTOR STRUCTURE OF INTEGRATED CIRCUIT

(76) Inventors: Chi-Lu Yu, Taipei County (TW); Rui-Huang Cheng, Taipei County (TW); Chien-Ming Lin, Hsin-Chu (TW); Ruei-Hao Huang, Kaohsiung County (TW)

Correspondence Address: NORTH AMERICA INTELLECTUAL PROPERTY CORPORATION, P.O. BOX 506, MERRIFIELD, VA, 22116, US

(21) Appl. No.: 11/968,205

(22) Filed: Jan. 2, 2008

(51) Int. Cl. H01L 21/425; H01L 29/36

(52) U.S. Cl. 257/491; 438/514; 257/E29.109; 257/E21.473

(57) ABSTRACT

A method for manufacturing an integrated circuit includes: performing ion implantation on a wafer to make a chip in the wafer have an original doping concentration; dividing the chip into a plurality of regions; and controlling at least one region of plurality of the regions to not have further ion implantation performed thereon, thereby making the region only have single ion implantation performed thereon utilize the original doping concentration as a doping concentration of N-wells or P-wells of transistors in the region. Additionally, the region corresponds to signal output circuits of the integrated circuit.

### BACKGROUND OF THE INVENTION

1. Field of the Invention

The present invention relates to semiconductor processes and semiconductor devices generated by the semiconductor processes, and more particularly, to a method for manufacturing an integrated circuit by utilizing an original doping concentration as a doping concentration of N-wells or P-wells of transistors of the signal output circuits in the integrated circuit and a semiconductor structure of the integrated circuit.

2. Description of the Prior Art

For data driving circuit(s) of a liquid crystal display or an organic electro-luminescence device (OLED) displayer, voltages outputted from signal output circuits of the data driving circuit directly correspond to gray values displayed on the displayer. Therefore, if the voltages outputted from the signal output circuits vary, gray values of the corresponding pixels of the displayer will also vary, and this influences the image quality. When a whole picture (or a picture corresponding to a data driving circuit) is displayed at the same gray value, all the signal output circuits of the data driving circuit(s) should output the same target voltages. However, if the signal output circuits of the data driving circuit(s) are unable to output the same voltages due to various factors, the poor uniformity of the image becomes obvious to the naked eye.

To solve the above-mentioned problem of non-uniformity of an image, every signal output circuit of the driving circuit of the displayer is required to output a stable voltage. Generally speaking, the signal output circuit of the driving circuit of the displayer is an amplifier. The threshold voltages of transistors of the amplifier determine a voltage slew rate of the amplifier, and the variation of the voltage slew rate will influence the output voltage value of the amplifier. Therefore, to make every signal output circuit of the driving circuit of the displayer output a stable voltage, the error of the threshold voltages of the transistors of each signal output circuit needs to be very small, so the voltage slew rates of all the signal output circuits will be close to each other.

During an integrated circuit manufacturing process, ion implantation is initially performed on a wafer to make N-wells or P-wells of transistors on the wafer have an original doping concentration. Then, a threshold voltage implantation (Vt-implantation) process is utilized to adjust doping concentration of the transistors on the wafer to make the transistors have the required threshold voltages. Considering the operating speed of the transistors, the threshold voltage values after performing threshold voltage implantation are generally lower than 1.5 volts. As the threshold voltage implantation process implants ions to the wafer in a scanning mode, however, there will be little difference in doping concentrations among different regions on the wafer. Additionally, because the threshold voltage implantation is a second ion implantation, under the interaction between different ions or different-type ions, the doping concentration difference among different regions will rise by a margin, resulting in great variation of the threshold voltage of the transistors on the wafer while the prior art threshold voltage value (about 1 volts) is used. FIG. 1 is a diagram illustrating variation of the threshold voltage values of prior art transistors of signal output circuits in a chip 100 when implanting ions to a wafer in the scanning mode. As shown in FIG. 1, the chip 100 comprises a plurality of signal output circuits 102. Due to the above-mentioned factors (utilizing scanning mode to perform ion implantation and the threshold voltage implantation being the second ion implantation) threshold voltage values of the transistors of the signal output circuits 102 at two sides of the chip 100 are Vt₁ and Vt₂. On average, the greater the distance between transistors in a chip, the larger the variation of the threshold voltage values of the transistors. Therefore, output voltage values of a chip of rectangular shape (e.g., driving circuit of a displayer) are usually less stable.

To solve the above-mentioned problems, prior art methods add clamp circuits into the signal output circuits in the chip to stabilize their voltage slew rate. However, adding the clamp circuits into the chip will increase design complexity and the chip area, and therefore results in higher manufacturing costs.

### SUMMARY OF THE INVENTION

It is therefore an objective of the present invention to provide a method for manufacturing an integrated circuit by utilizing an original doping concentration as a doping concentration of N-wells or P-wells of transistors at the signal output circuits of the integrated circuit and in the semiconductor structure of the integrated circuit, to solve the above-mentioned problems.

According to one embodiment of the present invention, a method for manufacturing an integrated circuit is disclosed. The method comprises: performing ion implantation on a wafer to make a chip in the wafer have an original doping concentration; dividing the chip into a plurality of regions; and controlling at least one region of the plurality of regions to not have further ion implantation performed thereon, thereby making the region only having single ion implantation performed thereon utilize the original doping concentration as a doping concentration of N-wells or P-wells of transistors in the region. Additionally, the region corresponds to signal output circuits of the integrated circuit.

According to one embodiment of the present invention, a semiconductor structure of an integrated circuit is disclosed. The semiconductor structure comprises: a chip comprising a plurality of regions, where at least one region of the plurality of regions utilizes an original doping concentration as doping concentrations of N-wells or P-wells of transistors in the region, wherein the original doping concentration is a doping concentration under signal ion implantation. Additionally, the region corresponds to signal output circuits of the integrated circuit.

According to the method for manufacturing the integrated circuit and related semiconductor structure disclosed by the present invention, the signal output circuits of the chip only undergo single ion implantation. Therefore, compared with other regions in the chip, the signal output circuits of the chip have a more uniform doping concentration, and the threshold voltages of transistors in the signal output circuits are higher and the output voltages are more stable.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a prior art diagram illustrating variation of the threshold voltage values of transistors of signal output circuits in a chip when implanting ions to a wafer in a scanning mode.

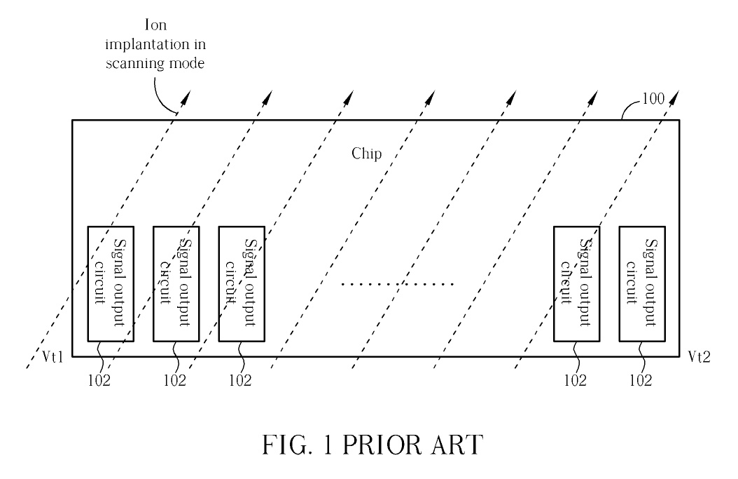

FIG. 2 is a diagram illustrating performing threshold voltage implantation on a chip according to one embodiment of the present invention.

FIG. 3 is a diagram illustrating the chip having undergone a threshold voltage implantation process.

FIG. 4 is a flowchart of the threshold voltage implantation process according to an embodiment of the present invention.

FIG. 5 is a circuit diagram of the signal output circuit shown in FIG. 2 according to a first embodiment of the present invention.

FIG. 6 is a circuit diagram of the signal output circuit shown in FIG. 2 according to a second embodiment of the present invention.

### DETAILED DESCRIPTION

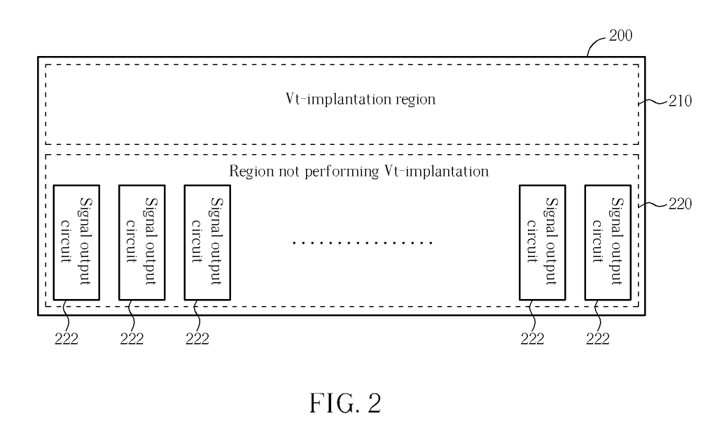

Please refer to FIG. 2. FIG. 2 is a diagram illustrating performing threshold voltage implantation on a chip 200 according to one embodiment of the present invention. As shown in FIG. 2, the chip 200 comprises a threshold voltage implantation region 210 and a region 220 not having threshold voltage implantation performed thereon, where the region 200 comprises a plurality of signal output circuits 222. To stabilize voltages outputted from the plurality of signal output circuits 222 in the region 220, the region 220 only has single ion implantation performed thereon to utilize an original doping concentration as a doping concentration of N-wells or P-wells of transistors in the region 220. Only performing single ion implantation and not performing threshold voltage implantation results in more uniform doping concentration of the N-wells or the P-wells of the transistors in the region 220. Therefore, the errors of the threshold voltages of the transistors of the signal output circuits 222 are smaller, and the signal output circuits 222 have closer voltage slew rates.

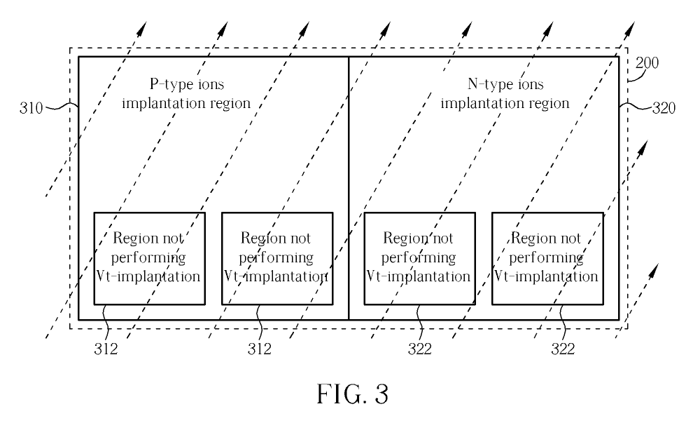

FIG. 3 is a diagram illustrating the chip 200 having undergone a threshold voltage implantation process. As shown in FIG. 3, during the manufacturing process of the chip 200, ion implantation is initially performed on a wafer to make N-wells and P-wells of all transistors in the chip 200 of the wafer have an original doping concentration, where a region 310 is a region having P-type ion implantation performed thereon, i.e. transistors in the region 310 have P-wells and the P-wells have an original doping concentration n_{P}_{_{—}}_{original}; and a region 320 is a region having N-type ion implantation performed thereon, i.e. transistors in the region 310 have N-wells and the N-wells have an original doping concentration n_{N}_{_{—}}_{original}. Generally speaking, the original doping concentration is an ion implantation with low concentration, being less than 10¹² ions/cm³. Additionally, the region 310 comprises a plurality of regions 312 not having threshold voltage implantation performed thereon, and the region 320 comprises a plurality of regions 322 not having threshold voltage implantation performed thereon, where the transistors in the plurality of regions 312 and 322 utilize the original doping concentration n_{P}_{_{—}}_{original} and n_{N}_{_{—}}_{original} as doping concentrations of the P-wells and the N-wells of the transistors in these regions. The transistors in the regions 312 and 322 have a threshold voltage value Vtₒᵣᵢ. In the regions 310 and 320, all regions except for the regions 312 and 322 have threshold voltage implantation performed thereon to adjust doping concentrations of N-wells and P-wells of transistors, and to achieve a required threshold voltage value Vtiₘₚ.

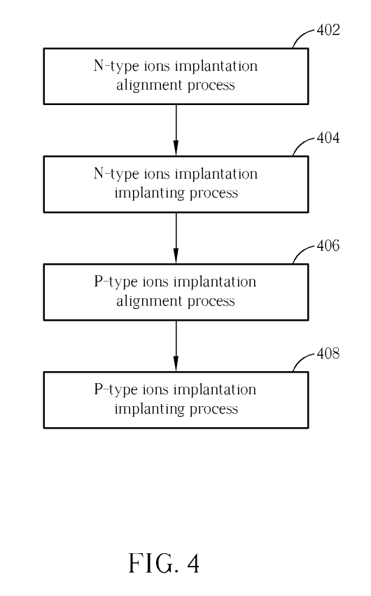

In practice, masks used in the threshold voltage implantation process mask the regions 312 and 322 to prevent these regions from being doped with other ions. FIG. 4 is a flowchart of the process of the threshold voltage implantation according to an embodiment of the present invention. The steps are as follows:

Step 402: N-type ions implantation alignment process.

Step 404: N-type ions implantation implanting process.

Step 406: P-type ions implantation alignment process.

Step 408: P-type ions implantation implanting process.

In Step 402, the N-type ions implantation alignment process represents steps of photo resist coating, mask alignment, photo resist development and after development inspection (ADI), where the mask masks the region 322. In Step 404, the N-type ions implantation implanting process represents steps of ion implantation, plasma cleaning, photo resist stripping and after etch inspection (AEI). In Step 406, the P-type ions implantation alignment process represents steps of mask alignment and after development inspection, where HVTP mask masks the region 312. In Step 408, the P-type ions implantation implanting process represents steps of ion implantation, plasma cleaning, photo resist stripping and after etch inspection.

It should be noted that the present invention can be implemented by many methods, and is not limited to the above embodiment and related methods. For example, if the transistors of the signal output circuits in the chip 200 are all N-type metal-oxide semiconductors (NMOS), the threshold voltage implantation process only implants one type of ion; by the same token, if the transistors of the signal output circuits in the chip 200 are all P-type metal-oxide semiconductors (PMOS), the threshold voltage implantation process implants only one type of ion. Additionally, Step 402 to Step 408 perform N-type ion implantation first, and then perform P-type ion implantation. Without departing from the threshold voltage implantation results of the present invention, sequences of the N-type and P-type ion implantations can be reversed, and these alternative processes are all within the scope of the present invention.

If the transistors in the region 220 of the chip 200 utilize the original doping concentration as the doping concentration of the N-wells and the P-wells, however, the threshold voltage values Vtₒᵣᵢ of the transistors will be higher than the threshold voltage values Vtᵢₘₚ of the transistors in the region 210, and the threshold voltage value Vtₒᵣᵢ will be between 1.5-2.5 volts. Therefore, the chip 200 is designed by considering the threshold voltage variation of the transistors in the region 220.

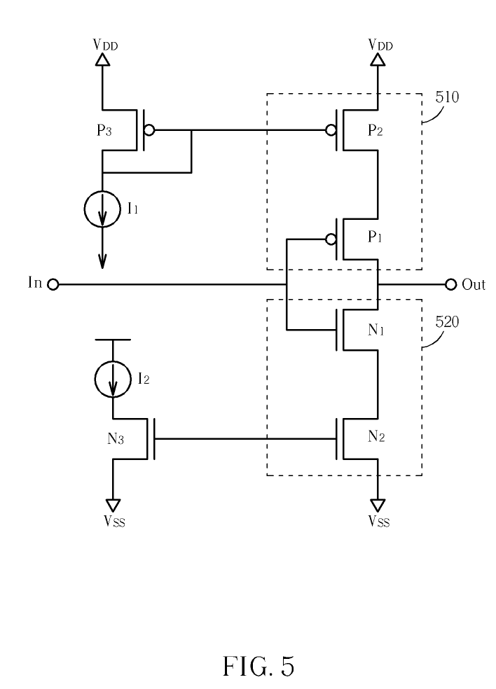

Additionally, in the above-mentioned embodiments of the present invention, all the transistors of the signal output circuits 222 in the chip 200 utilize the original doping concentration as the doping concentrations of the N-wells or the P-wells. However, considering functions of the signal output circuits 222, it is possible for N-wells or P-wells of only part of the transistors in the signal output circuits 222 to have the original doping concentration. Please refer to FIG. 5. FIG. 5 is a circuit diagram of the signal output circuit shown in FIG. 2 according to a first embodiment of the present invention. As shown in FIG. 5, a circuit 500 comprises two regions 510 and 520 not having threshold voltage implantation performed thereon, a PMOS P₃, an NMOS N₃, and two current sources I₁ and I₂, where the region 510 comprises two PMOS P₁ and P₂, and the region 520 comprises two NMOS N₁ and N₂. In this embodiment, when performing threshold voltage implantation, the mask in Step 402 masks the NMOS N₁ and N₂ to make their N-wells have the original doping concentration n_{N}_{_{—}}_{original} after the N-type ions implantation implanting process in Step 404. Then, the mask in Step 406 masks the PMOS P₁ and P₂ to make their P-wells have the original doping concentration n_{P}_{_{—}}_{original} after the P-type ions implantation implanting process in Step 408. It should be noted that, in this embodiment, because the PMOS P3 and the NMOS N3 do not influence the slew rate of the signal output circuit 500, the P-well of the PMOS P3 and N-wells of the NNOS N3 do not use the original doping concentration as their doping concentration.

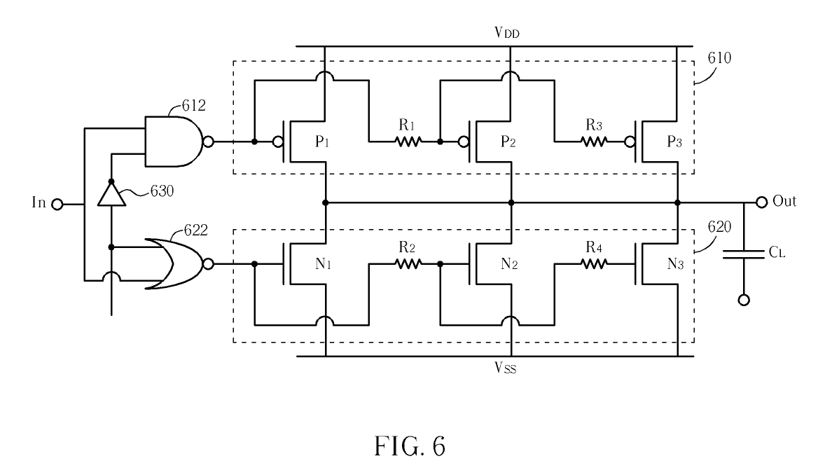

Please refer to FIG. 6. FIG. 6 is a circuit diagram of the signal output circuit shown in FIG. 2 according to a second embodiment of the present invention. As shown in FIG. 6, a circuit 600 comprises two regions 610 and 620 not having threshold voltage implantation performed thereon, a NAND gate 612, a NOR gate 622, an inverter 630, four resistors R₁, R₂, R₃, and R₄, and a loading capacitor CL, where the region 610 comprises three PMOS P₁, P₂ and P₃, and the region 620 comprises three NMOS N₁, N₂, and N₃. When performing threshold voltage implantation, the mask in Step 402 masks the NMOS N₁, N₂, and N₃ to make their N-wells have the original doping concentration n_{N}_{_{—}}_{original} after the N-type ions implantation implanting process in Step 404. Then, the mask in Step 406 masks the PMOS P₁, P₂, and P₃ to make their P-wells have the original doping concentration n_{P}_{_{—}}_{original} after the P-type ions implantation implanting process in Step 408. It should be noted that, because the NAND gate 612, the NOR gate 622, and the inverter 630 do not influence the slew rate of the signal output circuit 600, the P-wells or N-wells of the transistors in the NAND gate 612, the NOR gate 622, and the inverter 630 do not use the original doping concentration as their doping concentration.

Briefly summarized, the circuits 500 and 600 achieve uniform target voltages of the transistors in the signal output circuits, as long as transistors which may influence the slew rate do not have threshold voltage implantation performed thereon and utilize the original doping concentration as the doping concentration of their N-wells and P-wells, regardless of whether other transistors in the chip 200 have threshold voltage implantation performed thereon. These alternative designs are all within the scope of the present invention.

Additionally, one of the purposes of the present invention is to avoid adding clamp circuits into a chip, and ensuring that the plurality of signal output circuits in the chip have consistent threshold voltage values. According to the measuring results, in a chip manufactured according to the present invention, the errors of threshold voltage values of the transistors in the signal output circuits are about 20 mV (within three standard deviations). This value can be compared with errors of prior art threshold voltage values, which are between 25-30 mV. Additionally, because the transistors in the present invention have higher threshold voltage values, the ratio between the error voltage due to the errors of the threshold voltage values and the threshold voltage value is lower, and the variations of the slew rate are reduced. Therefore, utilizing the method for manufacturing the integrated circuit provided by the present invention significantly improves the uniformity of the outputted voltages, and the voltage slew rates of all the signal output circuits will be close to each other.

Briefly summarized, the method for manufacturing the integrated circuit provided by the present invention initially performs ion implantation on a wafer to make a chip of the wafer have an original doping concentration. After that, region(s) corresponding to signal output circuits in the chip do not have further ion implantation performed thereon, thereby making the region(s) only having single ion implantation performed thereon utilize the original doping concentration as a doping concentration of N-wells or P-wells of transistors in the region(s). Because the region(s) of the signal output circuits in the chip only have single ion implantation performed thereon, the errors of threshold voltages of the transistors in the region(s) are smaller, and the slew rates of the signal output circuits and outputted voltages are more stable.

Additionally, threshold voltage values can also be increased by increasing the thicknesses of gate electrodes of the transistors in the signal output circuits, and the voltage slew rates and the output voltages of the signal output circuits are more stable.

Those skilled in the art will readily observe that numerous modifications and alterations of the device and method may be made while retaining the teachings of the invention.

1-5. (canceled)

6. A semiconductor structure of an integrated circuit, comprising
a chip, comprising a plurality of regions, where at least one region of the plurality of regions utilizes an original doping concentration as doping concentrations of N-wells or P-wells of transistors in the region, wherein the original doping concentration is a doping concentration under signal ion implantation.

7. The semiconductor structure of claim 6, wherein the plurality of regions of the chip comprise:
at least one first region, wherein N-wells or P-wells of transistors in the first region have another doping concentration different from the original doping concentration; and
at least one second region, wherein N-wells or P-wells of transistors in the second region have the original doping concentration.

8. The semiconductor structure of claim 7, wherein the second region corresponds to signal output circuits of the integrated circuit.

9. The semiconductor structure of claim 6, wherein threshold voltages of the transistors in the region are between 1.5 volts and 2.5 volts.

10. The semiconductor structure of claim 6, wherein the integrated circuit is a driving circuit of a liquid crystal display or a driving circuit of an organic electro-luminescence device (OLED) display.
